(19) United States
(12) Patent Application Publication
(10) Pub. No.: US 2010/0085112 A1
(43) Pub. Date: Apr. 8, 2010

(54) Method of Manufacturing a Transistor, and Method of Controlling a Threshold Voltage of the Transistor

(76) Inventors: Sang-Hun Jeon, Yongin-si (KR); Moon-Sook Lee, Seoul (KR)

Correspondence Address: MYERS BIGEL SIBLEY & SAJOVEC, PO BOX 37428, RALEIGH, NC, 27627, US

(21) Appl. No.: 12/571,936

(22) Filed: Oct. 1, 2009

(30) Foreign Application Priority Data
Oct. 2, 2008 (KR) 10-2008-0097331

(51) Int. Cl. G05F 1/10; H01L 21/336

(52) U.S. Cl. 327/537; 438/306; 257/E21.409

(57) ABSTRACT

A transistor has a gate electrode, a gate insulation layer structure, a channel layer and source/drain layers. The gate insulation layer structure includes a lower gate insulation layer, a control layer for controlling a threshold voltage of the transistor, and an upper gate insulation layer. The channel layer contacts a surface of the gate insulation layer structure and vertically overlaps the gate electrode. The source/drain layers are adjacent to but not contacting the gate electrode.

### REFERENCE TO PRIORITY APPLICATION

This application claims priority from Korean Patent Application No. 10-2008-0097331 filed Oct. 2, 2008, the contents of which are hereby incorporated herein by reference.

### FIELD

Example embodiments relate to transistors, methods of manufacturing the transistors, and methods of controlling threshold voltages of the transistors.

### BACKGROUND

Chips used in radio frequency identifications (RFIDs), electronic article surveillance (EAS) tags, EAS sensors, etc. are generally manufactured by a printing process because of low costs.

However, types of channel layers formed by the printing process are limited, and transistors including the channel layers may not have good reproducibility. When nano-materials are used for the channel layers, a threshold voltage distribution of the transistor may be wider due to the non-uniformity of diameters of the nano-materials.

When transistors are manufactured by a printing process, heat treatment processes for doping impurities and activating the impurities are not easy to perform, so that source/drain regions are usually formed using a metal. The transistors having metal source/drain regions are majority carrier devices in which channels and carriers have the same conductive type. The majority carrier device is mainly operated in an accumulation mode. The transistor operated in the accumulation mode is turned on more easily than that operated in an inverse mode because a barrier between a source and a gate is relatively low, and thus the threshold voltage distribution thereof may be wider.

Accordingly, a transistor having a narrow threshold voltage distribution and being manufactured at a low cost is needed.

### SUMMARY

Example embodiments provide a transistor of which a threshold voltage is controllable.

Example embodiments provide a method of manufacturing a transistor of which a threshold voltage is controllable.

Example embodiments provide a method of controlling a threshold voltage of a transistor.

According to some example embodiments, there is provided a transistor. The transistor has a gate electrode, a gate insulation layer structure, a channel layer and source/drain layers. The gate insulation layer structure includes a lower gate insulation layer, a control layer for controlling a threshold voltage of the transistor, and an upper gate insulation layer. The channel layer contacts a surface of the gate insulation layer structure and vertically overlaps the gate electrode. The source/drain layers are adjacent to but not contacting the gate electrode.

In an example embodiment, the control layer may include a material having a band gap smaller than those of the lower and upper gate insulation layers.

In an example embodiment, the control layer may trap electrical charges for controlling the threshold voltage.

According to some example embodiments, there is provided a method of manufacturing a transistor. In the method, a gate electrode is formed. A gate insulation layer structure is formed to contact a surface of the gate electrode. The gate insulation layer structure includes a lower gate insulation layer, a control layer for controlling a threshold voltage of the transistor, and an upper gate insulation layer. A channel layer is formed to contact a surface of the gate insulation layer structure. Source/drain layers are formed to be adjacent to but not contacting the gate electrode.

In an example embodiment, electrical charges may be trapped so that the transistor may have a target threshold voltage.

In an example embodiment, when electrical charges are trapped, electrical signals may be applied to the source/drain layers.

In an example embodiment, at least one of the gate electrode, the control layer and the source/drain layers may be formed by a printing process.

According to some example embodiments, there is provided a method of controlling a threshold voltage of a transistor having a gate insulation layer structure, a channel layer and source/drain layers, wherein the gate insulation layer structure includes a lower gate insulation layer, a control layer and an upper gate insulation layer. In the method, an initial threshold voltage of the transistor is measured. Electrons are removed from the control layer when the initial threshold voltage is higher than a target threshold voltage. Electrons are stored in the control layer so that the transistor has a threshold voltage substantially the same as the target threshold voltage.

In an example embodiment, when the electrons are stored in the control layer, electrons may be trapped in the control layer, and then electrons stored at a shallow trap site of the control layer may be detrapped.

In an example embodiment, the electrons may be detrapped electrically or thermally.

According to example embodiments, a transistor having a narrow threshold voltage distribution may be manufactured at a low cost, and this transistor may be adapted to various chips used in RFIDs, EAS tags, EAS sensors, etc.

### BRIEF DESCRIPTION OF THE DRAWINGS

Example embodiments will be more clearly understood from the following detailed description taken in conjunction with the accompanying drawings. FIGS. 1 to 23 represent non-limiting, example embodiments as described herein.

FIG. 1 is a cross-sectional view illustrating a transistor in accordance with example embodiments;

FIG. 2 is a diagram illustrating energy band gaps of the lower and upper gate insulation layers 106 and 112, and the control layer 110 of the transistor when the control layer 110 includes a metal;

FIG. 3 is a diagram illustrating energy band gaps of the lower and upper gate insulation layers 106 and 112, and the control layer 110 of the transistor when the control layer 110 includes a semiconductor material or an insulating material;

FIGS. 4 to 10 are cross-section views illustrating a method of manufacturing the transistor of FIG. 1 in accordance with example embodiments;

FIG. 11 is a cross-sectional view illustrating a transistor in accordance with other example embodiments;

FIG. 12 is a cross-sectional view illustrating a transistor in accordance with still other example embodiments;

FIG. 13 is a cross-sectional view illustrating a transistor in accordance with still other example embodiments;

FIGS. 14 to 16 are cross-sectional views illustrating a method of manufacturing a transistor of FIG. 13 in accordance with example embodiments;

FIG. 17 is a cross-sectional view illustrating a semiconductor device including the transistor of FIG. 13;

FIG. 18 is a flowchart illustrating a first method of manufacturing the semiconductor device of FIG. 17 in accordance with example embodiments;

FIG. 19 is a cross-sectional view illustrating the first method of manufacturing the semiconductor device of FIG. 17 in accordance with example embodiments;

FIG. 20 is a flowchart illustrating a second method of manufacturing the semiconductor device of FIG. 17 in accordance with example embodiments;

FIG. 21 is a cross-sectional view illustrating the second method of manufacturing the semiconductor device of FIG. 17 in accordance with example embodiments;

FIG. 22 is a flowchart illustrating a third method of manufacturing the semiconductor device of FIG. 17 in accordance with example embodiments;

FIG. 23 is a cross-sectional view illustrating the third method of manufacturing the semiconductor device of FIG. 17 in accordance with example embodiments;

FIG. 24 is a flowchart showing a method of controlling a threshold voltage of a transistor including a control layer in accordance with example embodiments;

FIGS. 25A to 25C are energy band diagrams illustrating the charge storing states of a control layer in a transistor when electrons are stored in the control layer by an F-N tunneling method repeatedly;

FIG. 26 is a graph showing a threshold voltage distribution change before and after controlling the threshold voltage in accordance with example embodiments;

FIG. 27 is a flowchart showing a method of controlling a threshold voltage of a transistor including a control layer in accordance with other example embodiments;

FIG. 28 is a flowchart showing a method of controlling a threshold voltage of a transistor including a control layer in accordance with still other example embodiments;

FIGS. 29A to 29D are energy band diagrams illustrating states of a control layer in a transistor when electrons are stored in or detrapped from the control layer;

FIG. 30 is a graph showing a threshold voltage of a transistor when storing and detrapping steps are performed repeatedly;

FIG. 31 is a flowchart showing a method of controlling a threshold voltage of a transistor including a control layer in accordance with still other example embodiments;

FIG. 32 is a graph showing a threshold voltage of a transistor when storing and detrapping steps are performed;

FIG. 33 is a flowchart showing a method of controlling a threshold voltage of a transistor including a control layer in accordance with still other example embodiments;

FIG. 34A is a graph showing a charge trap density with respect to a trap energy when electrons are stored in a control layer, and FIG. 34B is a graph showing a charge trap density with respect to a trap energy when electrons are detrapped in a control layer; and

FIG. 35 is a graph showing the interface trap density with respect to the cycles.

### DETAILED DESCRIPTION OF THE EMBODIMENTS

This application claims priority under 35 U.S.C. §119 to Korean Patent Application No. 2008-97331, filed on Oct. 2, 2008 in the Korean Intellectual Property Office (KIPO), the contents of which are herein incorporated by reference in their entirety.

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

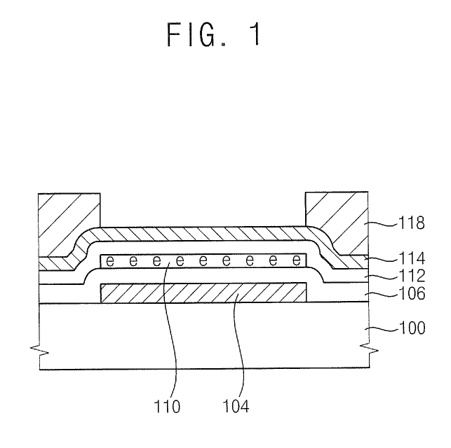

FIG. 1 is a cross-sectional view illustrating a transistor in accordance with example embodiments.

Referring to FIG. 1, a gate electrode 104 may be formed on a substrate 100. The substrate 100 may include a semiconductor material. Alternatively, the substrate 100 may include an insulating material such as plastic. The gate electrode 104 may be formed on an insulation region. An insulation layer (not shown) may be further formed between the substrate 100 and the gate electrode 104 when the substrate 100 does not include the insulating material.

A lower gate insulation layer 106 may be formed on the substrate 100 and the gate electrode 104. The lower gate insulation layer 106 may include an organic material, an inorganic material or a hybrid material.

A control layer 110 may be formed on the lower gate insulation layer 106. An upper gate insulation layer 112 may be formed on the control layer 110. The control layer 110 may vertically overlap the gate electrode 104. Alternatively, when the control layer 110 includes an insulating material, the control layer 110 may not vertically overlap the gate electrode 104.

The control layer 110 may include a material having a band gap lower than those of the lower and upper gate insulation layers 106 and 112. Thus, electrical charges may be stored at trap sites of the control layer 110. The control layer 110 may store electrical charges for controlling a threshold voltage of the transistor.

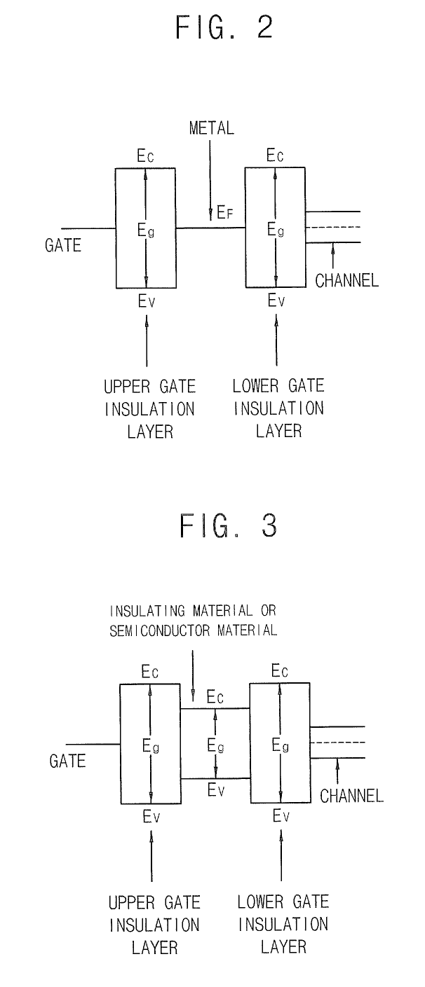

FIG. 2 is a diagram illustrating energy band gaps of the lower and upper gate insulation layers 106 and 112, and the control layer 110 of the transistor when the control layer 110 includes a metal. FIG. 3 is a diagram illustrating energy band gaps of the lower and upper gate insulation layers 106 and 112, and the control layer 110 of the transistor when the control layer 110 includes a semiconductor material or an insulating material.

Referring to FIG. 2, the control layer 110 may include a metal having a Fermi level lower than conduction bands of the lower and upper gate insulation layers 106 and 112.

Referring to FIG. 3, the control layer 110 may include a semiconductor material or an insulating material having a band gap smaller than those of the lower and upper gate insulation layers 106 and 112.

Alternatively, the control layer 110 may include an organic material or a nano-channel material. The nano-channel material may include a nanowire, a nano-plate, a nano-well, a nano-particle and/or a nano-dot.

In the present embodiment, the lower and upper gate insulation layers 106 and 112 may include silicon oxide, and the control layer 110 may include silicon nitride.

The lower and upper gate insulation layers 106 and 112 and the control layer 110 altogether may serve as a gate insulation layer structure of the transistor. The control layer 110 may not store data but control the threshold voltage of the transistor.

A channel layer 114 may be formed on the upper gate insulation layer 112. The channel layer 114 may include a nanowire, a nano-particle, an organic material, a hybrid material, etc. The channel layer 114 may include, for example, zinc oxide, gallium nitride, silicon, silicon germanium, cadmium sulfide, vanadium oxide, nickel monoxide, carbon, gallium arsenide, silicon carbide, zinc sulfide, zinc selenide, zinc telluride, cadmium selenide, cadmium telluride, mercury selenide, mercury telluride, copper arsenide, aluminum indium phosphorus, aluminum gallium arsenide, aluminum indium arsenide, aluminum gallium antimony, aluminum indium antimony, gallium indium phosphorus, gallium indium arsenide, gallium indium antimony, gallium phosphorus arsenide, gallium arsenide antimony, indium phosphorus arsenide, indium arsenide antimony, etc.

Source/drain layers 118 are formed on the channel layer 114. The source/drain layers 118 may not vertically overlap the gate electrode 104. The source/drain layers 118 may include a metal.

As illustrated above, the transistor may have the control layer 110 in the gate insulation layer structure. The threshold voltage of the transistor may be controlled by storing electrical charges into the control layer 110. When a plurality of transistors is formed on the substrate, the total threshold voltage of the transistors may be kept constant or the threshold voltages may be controlled to have different levels by controlling the amounts of electrical charges stored in each control layer 110.

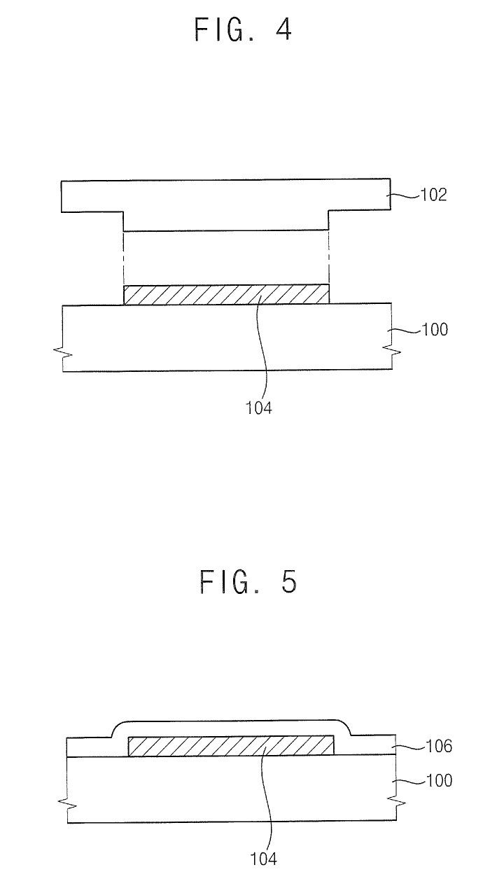

FIGS. 4 to 10 are cross-section views illustrating a method of manufacturing the transistor of FIG. 1 in accordance with example embodiments.

Referring to FIG. 4, the gate electrode 104 is formed on the substrate 100. An insulation layer (not shown) may be further formed on the substrate 100 before forming the gate electrode 104. The insulation layer may be formed by a spin coating process or a deposition process.

The gate electrode 104 may be formed by a printing process. Particularly, after pressing a first mold 102 on which a metal is coated onto the substrate 100, the first mold 102 may be detached from the substrate 100, so that the metal may be transferred from the first mold 102 to the substrate 100. The first mold 102 may have a protrusion on which the metal is coated. Alternatively, the gate electrode 104 may be formed by a deposition process and an etching process.

Referring to FIG. 5, the lower gate insulation layer 106 may be formed on the substrate 100 to cover the gate electrode 104. The lower gate insulation layer 106 may be formed by a deposition process or a spin coating process. The lower gate insulation layer 106 may be formed using an organic material, an inorganic material, or a hybrid material. For example, the lower gate insulation layer 106 may be formed using silicon oxide.

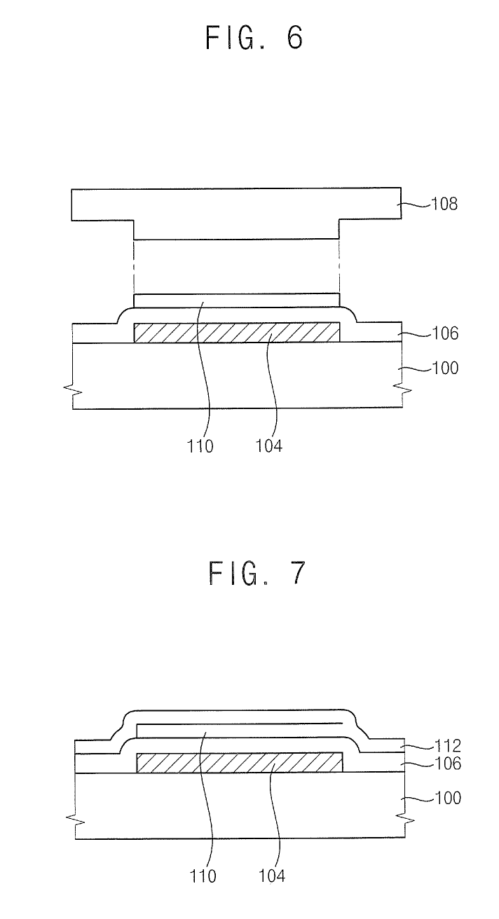

Referring to FIG. 6, the control layer 110 may be formed on the lower gate insulation layer 106. The control layer 110 may be formed to vertically overlap the gate electrode 104. The control layer 110 may be formed by a printing process. Particularly, after pressing a second mold 108 on which a material for forming the control layer 110 is coated onto the lower gate insulation layer 106, the second mold 108 may be detached from the lower gate insulation layer 106, so that the material for forming the control layer 110 may be transferred from the second mold 108 to the lower gate insulation layer 106.

The second mold 108 may have a protrusion on which the material for forming the control layer 110 is coated. The second mold 108 may have the same shape as that of the first mold 102. Alternatively, the control layer 110 may be formed by a deposition process and an etching process.

Referring to FIG. 7, the upper gate insulation layer 112 may be formed on the lower gate insulation layer 106 to cover the control layer 110. The upper gate insulation layer 112 may be formed by a deposition process or a spin coating process. In an example embodiment, the upper and lower gate insulation layers 112 and 106 may be formed using the same material, thereby having good interface characteristics. Alternatively, the upper and lower gate insulation layers 112 and 106 may be formed using different materials.

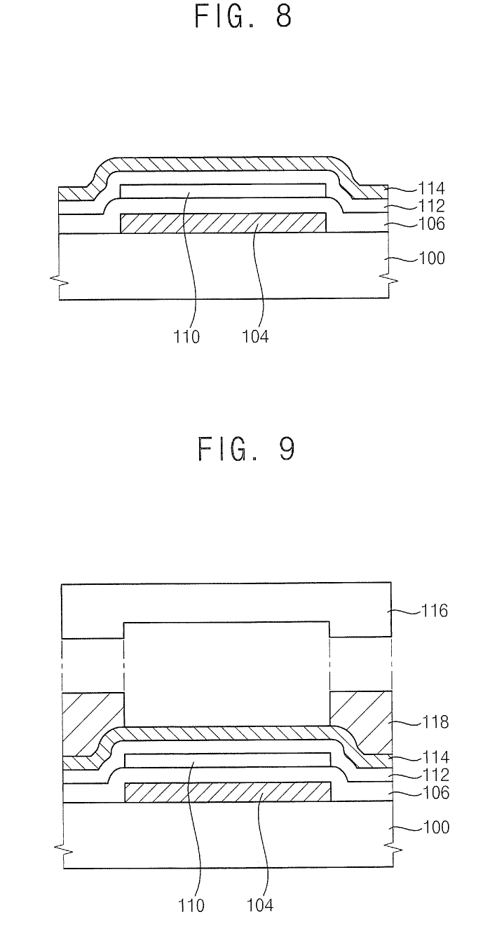

Referring to FIG. 8, the channel layer 114 may be formed on the upper gate insulation layer 112. The channel layer 114 may be formed by a deposition process or a spin coating process. Alternatively, the channel layer 114 may be formed by a printing process.

The channel layer 114 may be formed using a nanowire, a nano-particle, a nano-tube, an organic material, a hybrid material, etc. For example, the channel layer 114 may be formed using zinc oxide, gallium nitride, silicon, silicon germanium, cadmium sulfide, vanadium oxide, nickel monoxide, carbon, gallium arsenide, silicon carbide, zinc sulfide, zinc selenide, zinc telluride, cadmium selenide, cadmium telluride, mercury selenide, mercury telluride, copper arsenide, aluminum indium phosphorus, aluminum gallium arsenide, aluminum indium arsenide, aluminum gallium antimony, aluminum indium antimony, gallium indium phosphorus, gallium indium arsenide, gallium indium antimony, gallium phosphorus arsenide, gallium arsenide antimony, indium phosphorus arsenide, indium arsenide antimony, etc.

Referring to FIG. 9, the source/drain layers 118 may be formed on the channel layer 114. The source/drain layers 118 may be formed not to vertically overlap the gate electrode 104. The source/drain layers 118 may be formed using a metal by a printing process. Particularly, after aligning a third mold 116 on which a material for forming the source/drain layers 118 is coated with the gate electrode 104, the third mold 116 may be pressed onto the channel layer 114. The third mold 116 may be detached from the channel layer 114, so that the material for forming the source/drain layers 118 may be transferred from the third mold 116 to the channel layer 114. The third mold 116 may have a protrusion on which the material for forming the source/drain layers 118 is coated.

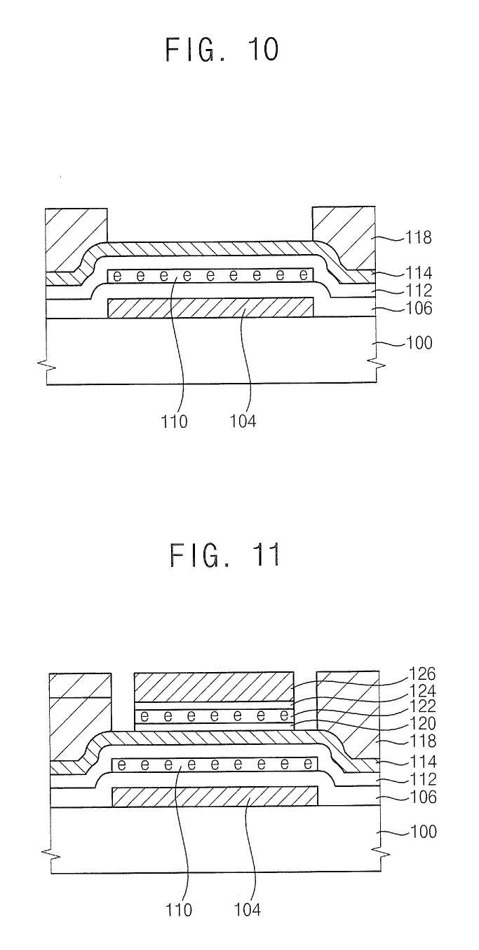

Referring to FIG. 10, electrical charges may be stored in the control layer 110 so that the threshold voltage of the transistor may be controlled. The control of the threshold voltage may be performed when the transistor does not have a target threshold voltage. The threshold voltage may be controlled by removing electrical charges from the control layer 110 or by storing electrical charges from the control layer 110.

The electrical charges may be removed or stored by applying an electrical signal to the gate electrode 104 and the source/drain layers 118. In an example embodiment, the electrical signal may be applied by directly contacting a probe tip with the gate electrode 104 and the source/drain layers 118. The transistor manufactured by a printing process may have a large size so that the probe tip may be easily contacted with the above elements.

Additionally, an RFID chip has a small number of transistors, e.g., about 1,000 to about 10,000 transistors therein, and thus controlling threshold voltages by using probe tips does not take much time.

A protection layer (not shown) may be further formed on the source/drain layers 118, thereby preventing damages from the probe tips.

A transistor that is a majority carrier device usually has a negative threshold voltage. When the transistor has a threshold voltage higher than a target voltage, electrical charges may be removed from the control layer 110 to decrease the threshold voltage. When the transistor has a threshold voltage lower than the target voltage, electrical charges may be stored in the control layer 110 to increase the threshold voltage.

The electrical charges may be removed or stored by a hot carrier injection (HCI) method or a Fowler-Nordheim (F-N) tunneling method.

FIG. 11 is a cross-sectional view illustrating a transistor in accordance with example embodiments.

The transistor illustrated with reference to FIG. 11 is similar to that of FIG. 1 except for a double-gate structure. Thus, like numerals refer to like elements, and repetitive explanations are omitted here.

Referring to FIG. 11, an upper gate insulation layer structure may be formed on the transistor of FIG. 1. Particularly, the upper gate insulation layer structure including a second lower gate insulation layer 120, a second control layer 122 and a second upper gate insulation layer 124 may be formed on the channel layer 114.

The upper gate insulation layer structure may be formed to vertically overlap the control layer 110 or the gate electrode 104. The upper gate insulation layer structure may not contact the source/drain layers 118.

The second control layer 122 may store electrical charges for controlling the threshold voltage of the transistor.

An upper gate electrode 126 may be formed on the upper gate insulation layer structure to vertically overlap the gate electrode 104. The upper gate electrode 126 may be formed not to contact the source/drain layers 118.

FIG. 12 is a cross-sectional view illustrating a transistor in accordance with example embodiments.

The transistor illustrated with reference to FIG. 12 is similar to that of FIG. 1 except for a double-gate structure. Thus, like numerals refer to like elements, and repetitive explanations are omitted here.

Referring to FIG. 12, a second gate insulation layer 130 may be formed on the transistor of FIG. 1. Particularly, the second gate insulation layer 130 may be formed on the channel layer 114. The second gate insulation layer 130 may be a single layer, and may not include a control layer. The second gate insulation layer 130 may not contact the source/drain layers 118.

An upper gate electrode 132 may be formed on the second gate insulation layer 130. The upper gate electrode 132 may vertically overlap the gate electrode 104. The upper gate electrode 132 may be formed not to contact the source/drain layers 118.

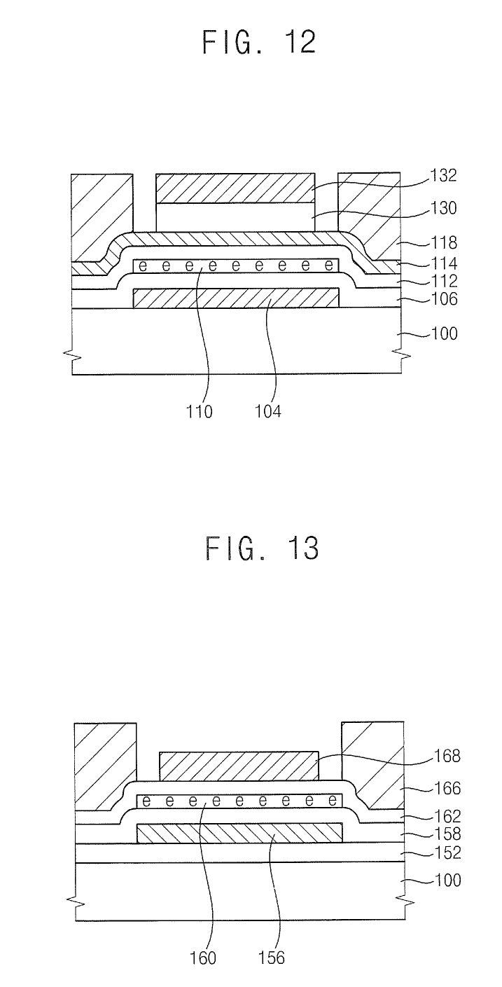

FIG. 13 is a cross-sectional view illustrating a transistor in accordance with example embodiments.

The transistor illustrated with reference to FIG. 13 may have a top-gate structure.

Referring to FIG. 13, an insulation layer 152 may be formed on the substrate 100. The substrate 100 may include a semiconductor material. Alternatively, the substrate 100 may include an insulating material such as plastic. The insulation layer 152 may not be formed when the substrate 100 includes the insulating material.

A channel layer 156 may be formed on the insulation layer 152. The channel layer 156 may include a nanowire, a nano-particle, an organic material, a hybrid material, etc. The channel layer 156 may be formed by a printing process. The channel layer 156 may entirely or partially cover the insulation layer 152.

A gate insulation layer structure including a lower gate insulation layer 158, a control layer 160 and an upper gate insulation layer 162 may be formed on the channel layer 156. The control layer 160 may be formed to vertically overlap the channel layer 156.

The control layer 160 may include a material having a band gap lower than those of the lower and upper gate insulation layers 158 and 162. The control layer 160 may store electrical charges for controlling a threshold voltage of the transistor.

A gate electrode 168 may be formed on the upper gate insulation layer 162. The gate electrode 168 may be formed to vertically overlap the channel layer 156.

Source/drain layers 166 may be formed on the upper gate insulation layer 162. The source/drain layers 166 may be formed adjacent to the gate electrode 168, however, the source/drain layers 166 may not contact the gate electrode 168. The source/drain layers 166 may be formed using a metal. The source/drain layers 168 may contact the upper gate insulation layer 162. Alternatively, the source/drain layers 168 may contact the channel layer 156.

FIGS. 14 to 16 are cross-sectional views illustrating a method of manufacturing a transistor of FIG. 13 in accordance with example embodiments.

Referring to FIG. 14, the insulation layer 152 may be formed on the substrate 100. The insulation layer 152 may be formed by a spin coating process or a deposition process.

The channel layer 156 may be formed on the insulation layer 152. The channel layer 156 may be formed by a spin coating process, a deposition process or a printing process. When the channel layer 156 is formed by the spin coating process or the deposition process, the channel layer 156 may be formed entirely on the insulation layer 152. When the channel layer 156 is formed by the printing process, the channel layer 156 may be formed on a specific portion of the insulation layer 152.

In the present embodiment, the channel layer 156 may be formed by a printing process. Particularly, after pressing a first mold 154 on which a material for forming the channel layer 156 onto the insulation layer 152, the first mold 154 may be detached from the insulation layer 152, so that the material for forming the channel layer 156 may be transferred from the first mold 156 to the insulation layer 152. The channel layer 156 may be formed using a nanowire, a nano-particle, an organic material, a hybrid material, etc.

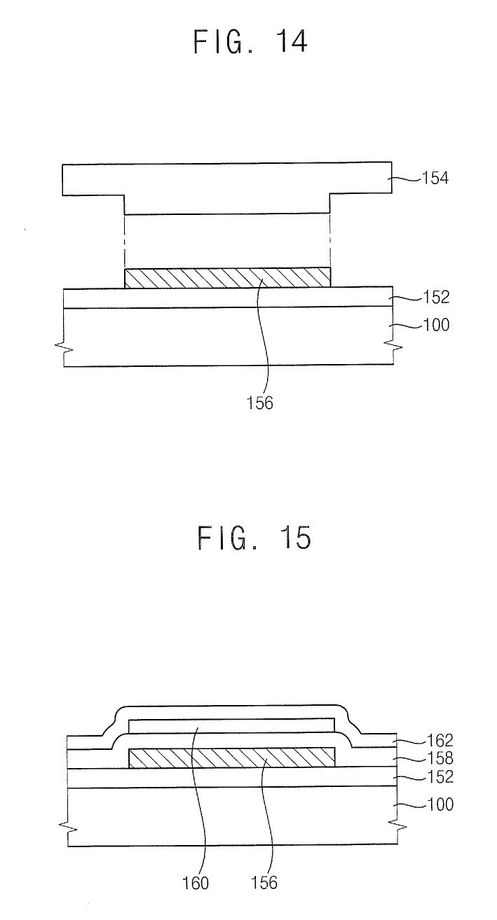

Referring to FIG. 15, a lower gate insulation layer 158 may be formed on the insulation layer 152 to cover the channel layer 156. The lower gate insulation layer 158 may be formed by a deposition process or a spin coating process.

A control layer 160 may be formed on the lower gate insulation layer 158. The control layer 160 may be formed to vertically overlap the channel layer 156. The control layer 160 may be formed by a printing process.

An upper gate insulation layer 162 may be formed on the control layer 160 and the lower gate insulation layer 158. The upper gate insulation layer 162 may be formed by a deposition process or a spin coating process.

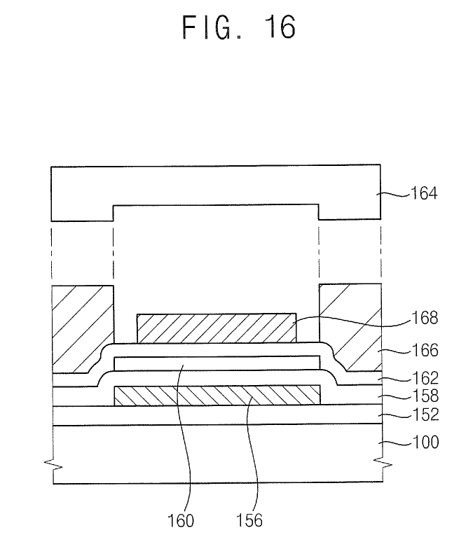

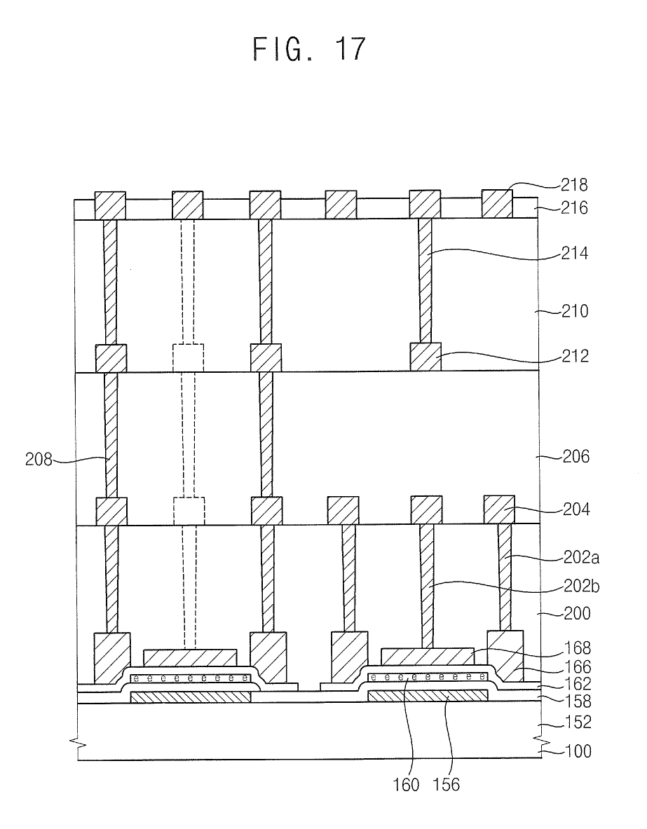

Referring to FIG. 16, a gate electrode 168 may be formed on the upper gate insulation layer 162. The gate electrode 168 may be formed by a printing process.

Source/drain layers 166 may be formed on the upper gate insulation layer 162. Alternatively, the source/drain layers 166 may contact the channel layer 156. The source/drain layers 166 may not contact the gate electrode 168. The source/drain layers 166 may be formed using a metal. The source/drain layers 166 may be formed by a printing process using a second mold 164.

As illustrated with reference to FIG. 13, electrical charges may be removed from or stored in the control layer 160 to control a threshold voltage of the transistor when the transistor does not have a target threshold voltage.

FIG. 17 is a cross-sectional view illustrating a semiconductor device including the transistor of FIG. 13.

Referring to FIG. 17, a plurality of the transistors of FIG. 13 may be formed on the substrate 100.

A first insulating interlayer 200 may be formed on the substrate 100 to cover the transistors.

A first plug 202a electrically connected to the source/drain layers 166 may be formed through the first insulating interlayer 200. A second plug 202b electrically connected to the gate electrode 168 may be formed through the first insulating interlayer 200.

A plurality of first conductive patterns 204 electrically connected to the first and second plugs 202a and 202b may be formed on the first insulating interlayer 200. The first and second plugs 202a and 202b and the first conductive patterns 204 may include a metal.

A second insulating interlayer 206 may be formed on the first insulating interlayer 200 to cover the first conductive patterns 204.

A plurality of third plugs 208 electrically connected to the first conductive patterns 204 may be formed through the second insulating interlayer 206. A plurality of second conductive patterns 212 electrically connected to the third plugs 208 may be formed on the second insulating interlayer 206.

A third insulating interlayer 210 may be formed on the second insulating interlayer 206 to cover the second conductive patterns 212. A plurality of fourth plugs 214 electrically connected to the second conductive patterns 212 may be formed through the third insulating interlayer 210. A plurality of pad electrodes 218 electrically connected to the fourth plugs 214 may be formed on the third insulating interlayer 210. A protection layer 216 may be formed on the third insulating interlayer 210. Top surfaces of the pad electrodes 218 may not be covered by the protection layer 216.

A metal wiring structure including the plugs 202a, 202b, 208 and 214 and the conductive patterns 204 and 212 may apply voltages of different levels to each transistor having the gate electrode 168 and the source/drain layers 166. The metal wiring structure may have multi-layered structure.

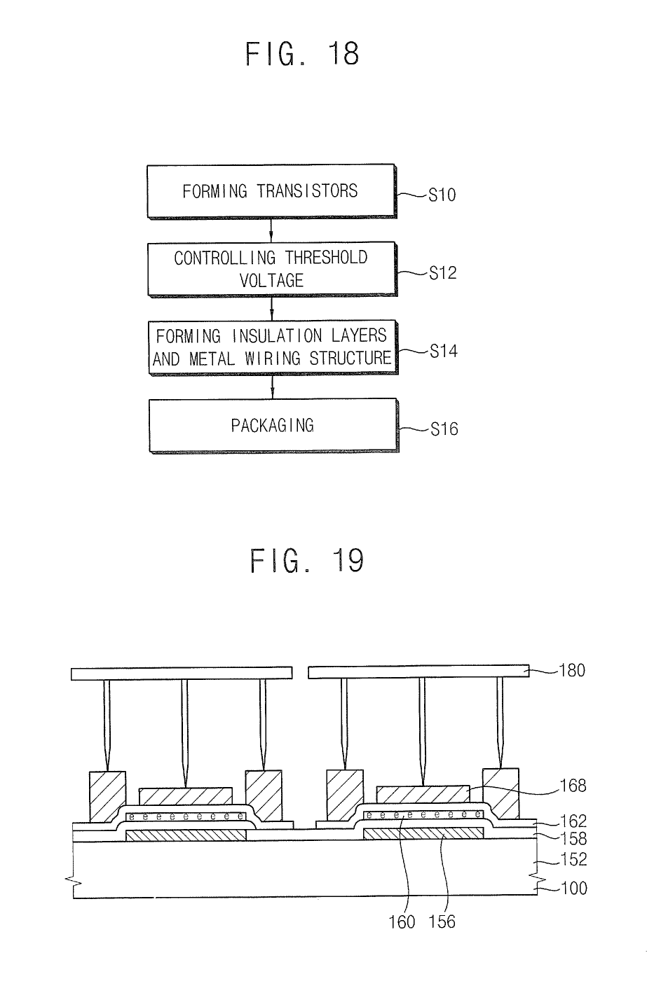

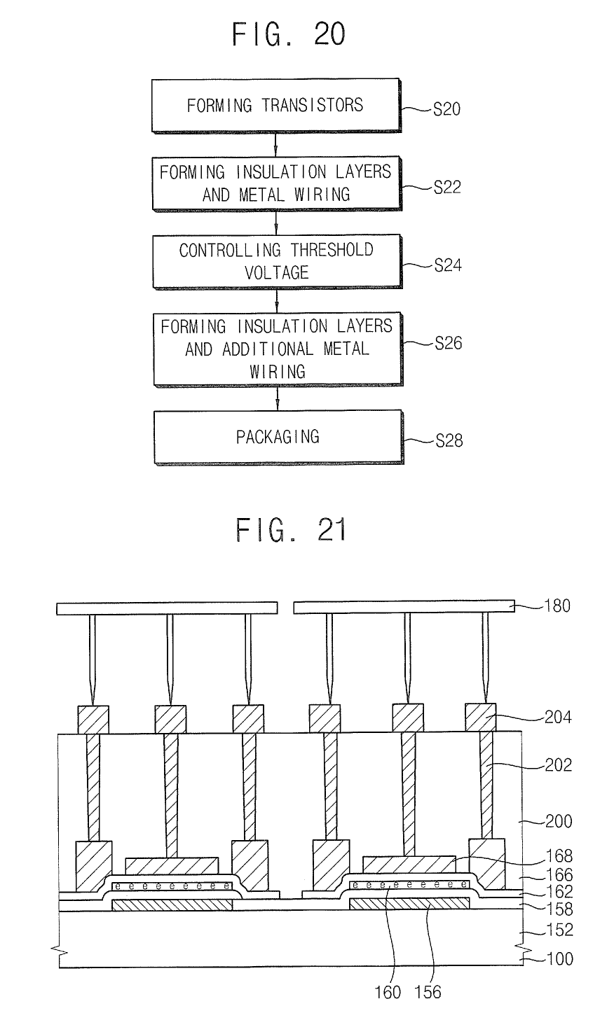

FIG. 18 is a flowchart illustrating a first method of manufacturing the semiconductor device of FIG. 17 in accordance with example embodiments. FIG. 19 is a cross-sectional view illustrating the first method of manufacturing the semiconductor device of FIG. 17 in accordance with example embodiments.

The method of manufacturing the transistor included in the semiconductor device of FIG. 17 has been illustrated with reference to FIGS. 14 to 16, and thus repetitive explanations thereof are omitted here.

In step S10, a plurality of transistors may be formed on the substrate 100 by performing processes illustrated with reference to FIGS. 14 to 16. The transistors may be horizontally distant from each other. The gate electrode 168 and the source/drain layers 166 of each transistor may have wide areas enough to be contacted by probe tips easily.

In step S12, as illustrated with reference to FIG. 16, electrical charges may be removed from or stored in the control layer 160 so that a threshold voltage of the transistor may be controlled when the transistor does not have a target threshold voltage.

Particularly, referring to FIGS. 18 and 19, the gate electrode 168 and the source/drain layers 166 of each transistor may be contacted with a probe tip 180. Each threshold voltage of each transistor may be measured by the probe tip 180. The transistors may have non-uniform threshold voltages because the transistors may be manufactured by a printing process or a spin coating process.

Negative charges, e.g., electrons in the control layer 160 of a transistor having a threshold voltage higher than a target threshold voltage may be removed, while electrons may be stored in the control layer 160 of a transistor having a threshold voltage lower than a target threshold voltage. The electrons may be stored or removed by a HCI method or an F-N tunneling method. Thus, each transistor may have a threshold voltage substantially the same as the target threshold voltage.

Alternatively, after removing electrons from the control layer 160 of all transistors regardless of the threshold voltages, electrons may be stored in the control layer 160 until each transistor has the target threshold voltage. That is, after the threshold voltage of each transistor becomes in the lowest state, each transistor may be controlled to have the target threshold voltage by storing electrons in the control layer 160.

Referring now to FIGS. 17 and 18, in step S14, the first insulating interlayer 200 may be formed on the substrate 100 to cover the transistors. The first and second plugs 202a and 202b may be formed through the first insulating interlayer 200 to be electrically connected to the source/drain layers 166 and the gate electrode 168. The first conductive patterns 204 may be formed on the first insulating interlayer 200 to be electrically connected to the first and second plugs 202a and 202b.

The second insulating interlayer 206 may be formed on the first insulating interlayer 200. The third plugs 208 may be formed through the second insulating interlayer 206 to be electrically connected to the first conductive patterns 204. The second conductive patterns 212 may be formed on the second insulating interlayer 206 to be electrically connected to the third plugs 208.

The above processes for forming plugs and conductive patterns may be repeatedly performed to form a multi-layered metal wiring structure, and the protection layer 216 may be formed on the multi-layered metal wiring structure.

In step S16, a process for packaging may be performed to complete the semiconductor device.

FIG. 20 is a flowchart illustrating a second method of manufacturing the semiconductor device of FIG. 17 in accordance with example embodiments. FIG. 21 is a cross-sectional view illustrating the second method of manufacturing the semiconductor device of FIG. 17 in accordance with example embodiments.

The method of manufacturing the transistor included in the semiconductor device of FIG. 17 has been illustrated with reference to FIGS. 14 to 16, and thus repetitive explanations thereof are omitted here.

In step S20, a plurality of transistors may be formed on the substrate 100 by performing processes illustrated with reference to FIGS. 14 to 16, except that the control of the threshold voltage is not performed.

Referring to FIGS. 20 and 21, in step S22, the first insulating interlayer 200 may be formed on the substrate 100 to cover the transistors. The first and second plugs 202a and 202b may be formed through the first insulating interlayer 200 to be electrically connected to the source/drain layers 166 and the gate electrode 168. The first conductive patterns 204 may be formed on the first insulating interlayer 200 to be electrically connected to the first and second plugs 202a and 202b. The first and second plugs 202a and 202b and the first conductive patterns 204 may be formed using a metal.

In step S24, the control of the threshold voltage may be performed.

Particularly, after measuring the threshold voltage of each transistor by contacting the probe tip 180 with the first conductive patterns 204 electrically connected to the gate electrode 168 and the source/drain layers 166, negative charges, e.g., electrons may be removed from or stored in the control layer 160. Thus, each transistor may be controlled to have the target threshold voltage.

Referring now to FIG. 20, in step S26, the second insulating interlayer 206 may be formed on the first insulating interlayer 200. The third plugs 208 may be formed through the second insulating interlayer 206 to be electrically connected to the first conductive patterns 204. The second conductive patterns 212 may be formed on the second insulating interlayer 206 to be electrically connected to the third plugs 208. The above processes for forming plugs and conductive patterns may be repeatedly performed to form a multi-layered metal wiring structure, and the protection layer 216 may be formed on the multi-layered metal wiring structure.

In step S28, a process for packaging may be performed to complete the semiconductor device.

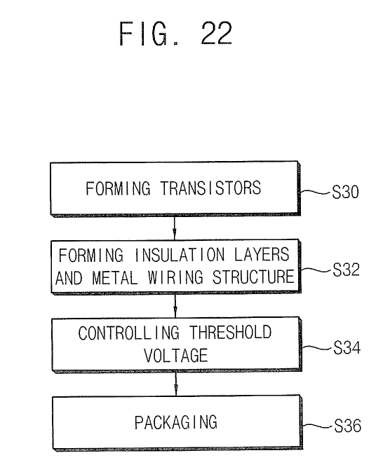

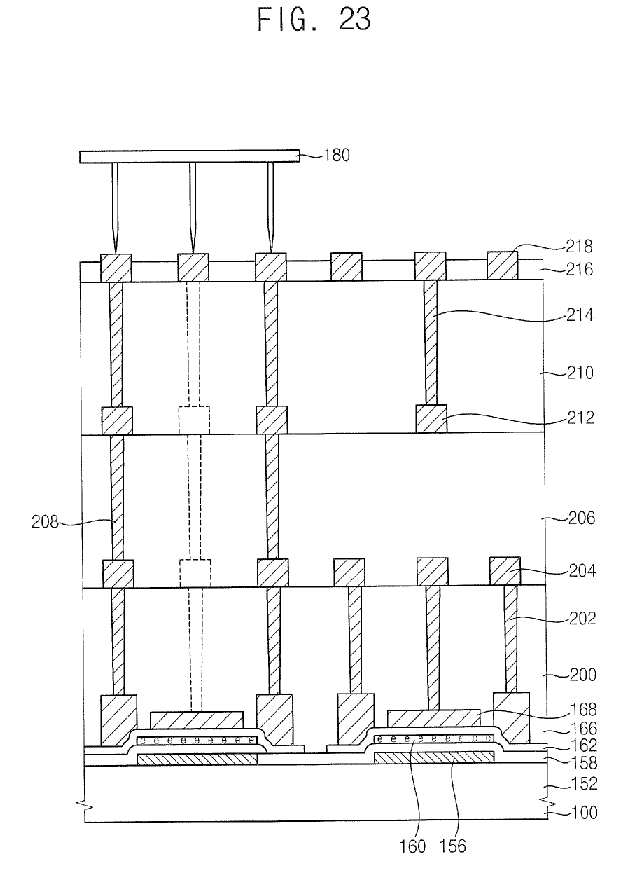

FIG. 22 is a flowchart illustrating a third method of manufacturing the semiconductor device of FIG. 17 in accordance with example embodiments. FIG. 23 is a cross-sectional view illustrating the third method of manufacturing the semiconductor device of FIG. 17 in accordance with example embodiments.

The method of manufacturing the transistor included in the semiconductor device of FIG. 17 has been illustrated with reference to FIGS. 14 to 16, and thus repetitive explanations thereof are omitted here.

In step S30, a plurality of transistors may be formed on the substrate 100 by performing processes illustrated with reference to FIGS. 14 to 16, except that the control of the threshold voltage is not performed.

Referring to FIGS. 22 and 23, in step S32, the first insulating interlayer 200 may be formed on the substrate 100 to cover the transistors. The first and second plugs 202a and 202b may be formed through the first insulating interlayer 200 to be electrically connected to the source/drain layers 166 and the gate electrode 168. The first conductive patterns 204 may be formed on the first insulating interlayer 200 to be electrically connected to the first and second plugs 202a and 202b. The first and second plugs 202a and 202b and the first conductive patterns 204 may be formed using a metal.

The second insulating interlayer 206 may be formed on the first insulating interlayer 200. The third plugs 208 may be formed through the second insulating interlayer 206 to be electrically connected to the first conductive patterns 204. The second conductive patterns 212 may be formed on the second insulating interlayer 206 to be electrically connected to the third plugs 208. The above processes for forming plugs and conductive patterns may be repeatedly performed to form a multi-layered metal wiring structure, and the protection layer 216 may be formed on the multi-layered metal wiring structure. The pad electrodes 218 may not be covered by the protection layer 216.

In step 34, the control of the threshold voltage may be performed. Particularly, after measuring the threshold voltage of each transistor by contacting the probe tip 180 with the pad electrodes 204 electrically connected to the gate electrode 168 and the source/drain layers 166, negative charges, e.g., electrons may be removed from or stored in the control layer 160. Thus, each transistor may be controlled to have the target threshold voltage.

In step S36, a process for packaging may be performed to complete the semiconductor device.

Until now, the method of manufacturing the transistor of FIG. 17 has been illustrated, however, the other transistors illustrated with reference to FIGS. 1, 11 and 12 may be also manufactured by substantially the same or similar method.

Hereinafter, a method of controlling a threshold voltage of a transistor may be explained. The method may be applied to the step of controlling the threshold voltage of the transistor. The method may be also applied to various transistors having a gate insulation layer including a charge storing layer therein.

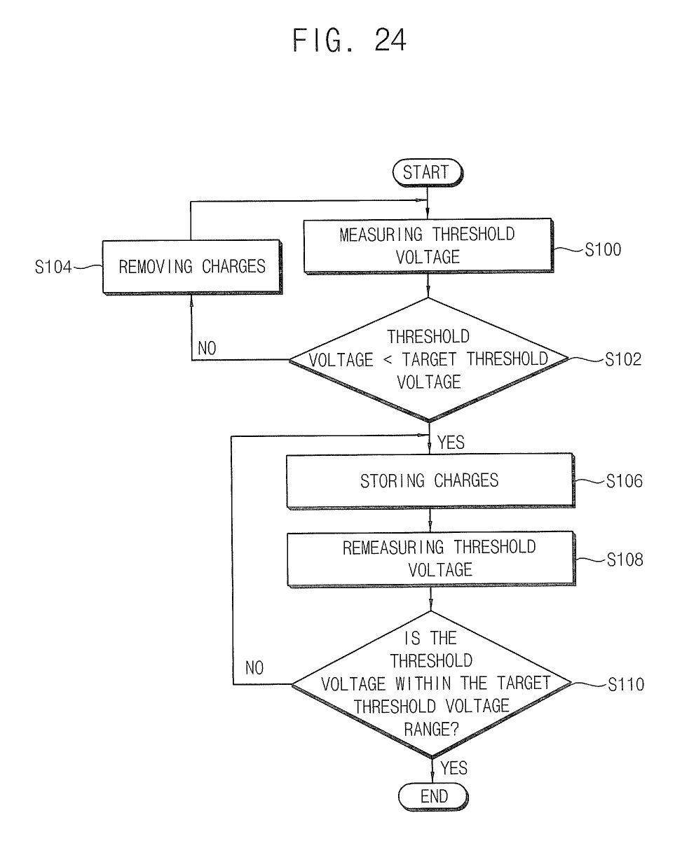

FIG. 24 is a flowchart showing a method of controlling a threshold voltage of a transistor including a control layer in accordance with example embodiments.

Referring to FIG. 24, in step S100, an initial threshold voltage of the transistor may be measured.

In step S102, the measured threshold voltage and a range of a target threshold voltage may be compared to each other.

If the measured threshold voltage is higher than the target threshold voltage range, in step S104, negative charges, e.g., electrons may be removed from the control layer. After removing the electrons, the threshold voltage may be measured again, and compared with the target threshold voltage range again.

If the measured threshold voltage is lower than the target threshold voltage range, in step S106, electrons may be stored in the control layer. The electrons may be stored by a HCI method or an F-N tunneling method.

In step S108, the threshold voltage of the transistor may be measured again.

In step S110, whether the measured threshold voltage is within the target threshold voltage range is decided.

If the measured threshold voltage is not within the target threshold voltage range, the steps S106 and 5108 may be performed again. However, if the measured threshold voltage is within the target threshold voltage range, the control of the threshold voltage may be finished.

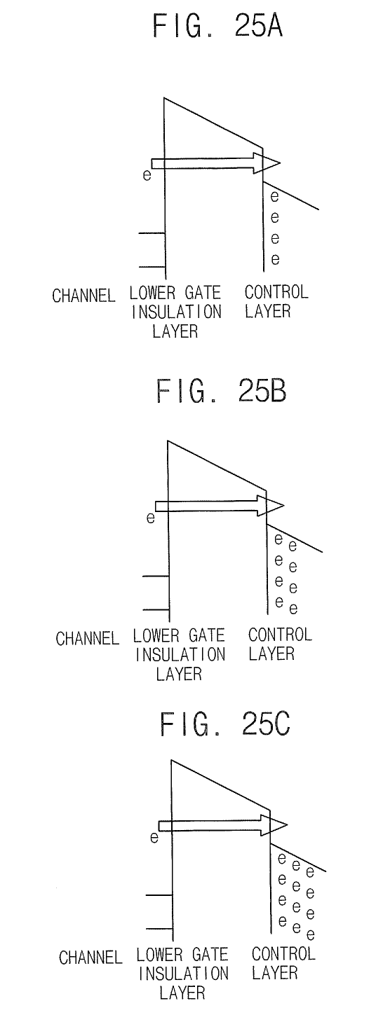

FIGS. 25A to 25C are energy band diagrams illustrating the charge storing states of a control layer in a transistor when electrons are stored in the control layer by an F-N tunneling method repeatedly. Particularly, FIGS. 25A, 25B and 25C are energy band diagrams of a channel layer, a lower gate insulation layer and the control layer at first, second and third storing steps, respectively.

As shown in FIGS. 25A to 25C, electrons tunneling from the channel layer may be stored in the control layer because of the band gaps of the control layer and the lower gate insulation layer. As the storing step is performed repeatedly, the amount of electrons stored in the control layer may be increased.

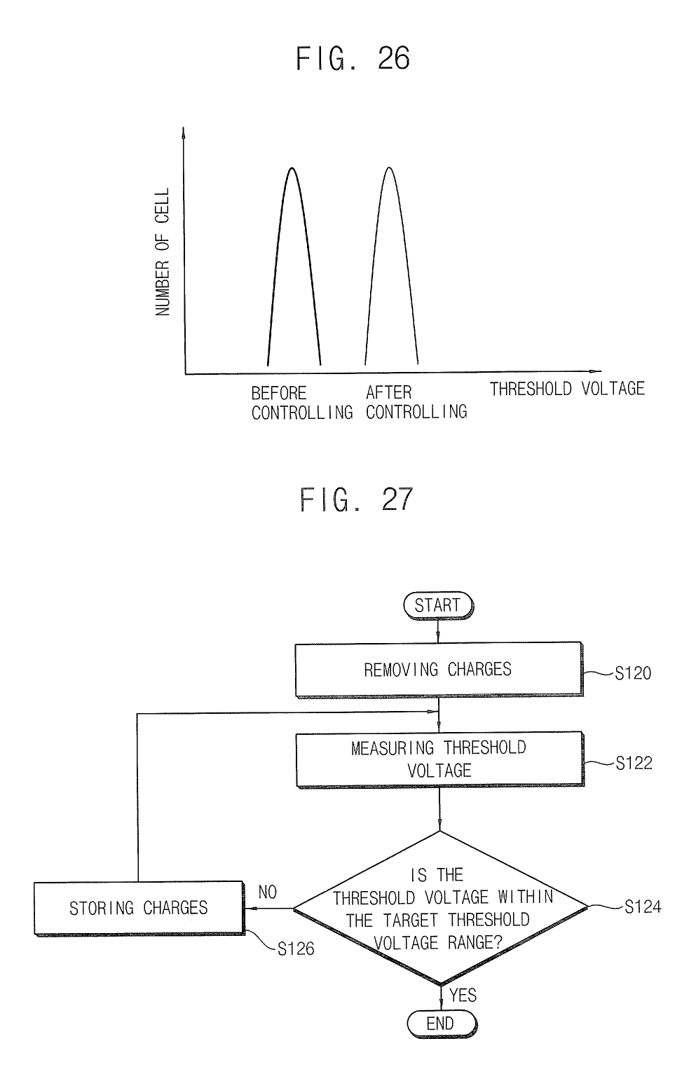

FIG. 26 is a graph showing a threshold voltage distribution change before and after controlling the threshold voltage in accordance with example embodiments.

Referring to FIG. 26, the threshold voltage distribution shifts from left to right after controlling the threshold voltage, which means the value of the threshold voltage increases. That is, the threshold voltage may have a higher value by storing electrons in the control layer.

FIG. 27 is a flowchart showing a method of controlling a threshold voltage of a transistor including a control layer in accordance with other example embodiments.

Referring to FIG. 27, in step S120, negative charges, e.g., electrons in the control layer may be removed. Thus, the threshold voltage of the transistor may become in the lowest state.

In step S122, an initial threshold voltage of the transistor may be measured.

In step S124, the measured threshold voltage and a range of a target threshold voltage may be compared to each other.

If the measured threshold voltage is lower than the target threshold voltage range, in step S126, electrons may be stored in the control layer. The electrons may be stored by a HCI method or an F-N tunneling method.

In step S122, the threshold voltage may be measured again, and in step S124, the measured threshold voltage and the target threshold voltage range may be compared to each other again.

If the measured threshold voltage is not within the target threshold voltage range, the steps S126, 5122 and 5124 may be performed again.

If the measured threshold voltage is within the target threshold voltage range, the control of the threshold voltage may be finished.

The above method is to increase the threshold voltage up to the target threshold voltage range by storing electrons in the control layer after decreasing the threshold voltage initially.

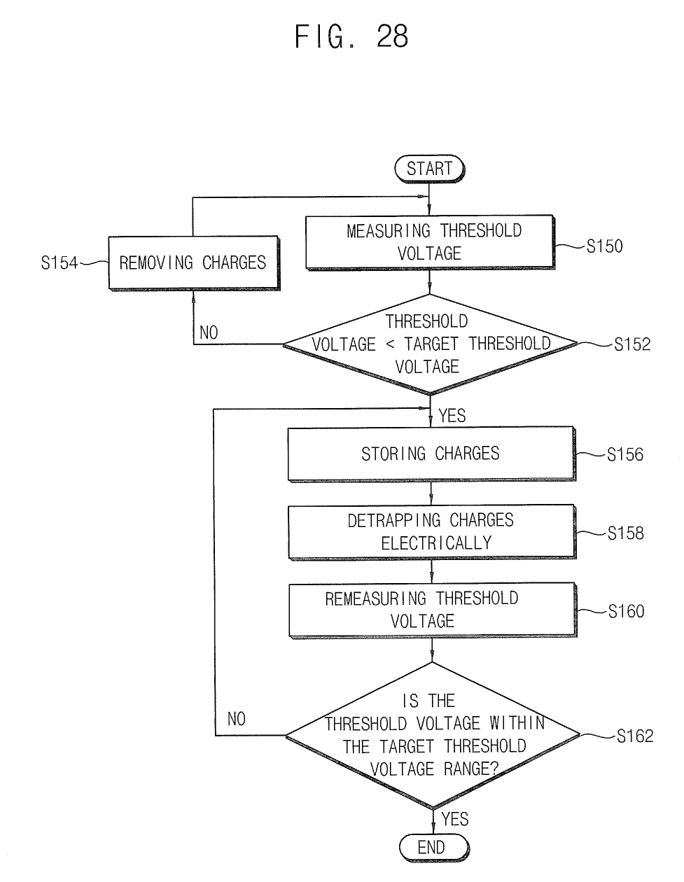

FIG. 28 is a flowchart showing a method of controlling a threshold voltage of a transistor including a control layer in accordance with still other example embodiments.

Referring to FIG. 28, in step S150, an initial threshold voltage of the transistor may be measured.

In step S152, the measured threshold voltage and a range of a target threshold voltage may be compared to each other.

If the measured threshold voltage is higher than the target threshold voltage range, in step S154, negative charges, e.g., electrons in the control layer may be removed.

In step S150, the threshold voltage of the transistor may be measured again.

If the measured threshold voltage is lower than the target threshold voltage range, in step S156, electrons may be stored in the control layer. The electrons may be stored by a HCI method or an F-N tunneling method.

In step S158, electrons stored at a shallow trap site in the control layer may be detrapped. The detrapping step may be performed electrically.

The amount of electrons stored in the control layer preferably does not change so that the threshold voltage may not be changed. However, the electrons stored at a shallow trap site may be easily removed by noises, thereby changing the amount of the electrons. Thus, the electrons stored at the shallow trap site may be removed before completing the control of the threshold voltage.

The detrapping step may be performed by an F-N erase method including applying a negative voltage to a gate electrode and grounding a channel layer and source/drain layers. When the F-N erase method is performed, the level of an operation voltage may be controlled so that electrons stored only at a shallow trap site may be removed. That is, the operation voltage may have a lower level than that of an operation voltage at which an F-N programming is performed.

In step S160, the threshold voltage may be measured again, and in step S162, whether the measured threshold voltage is within the target threshold voltage range is decided.

If the measured threshold voltage is not within the target threshold voltage range, the steps S156, 5158 and 5160 may be performed again.

If the measured threshold voltage is within the target threshold voltage range, the control of the threshold voltage may be finished.

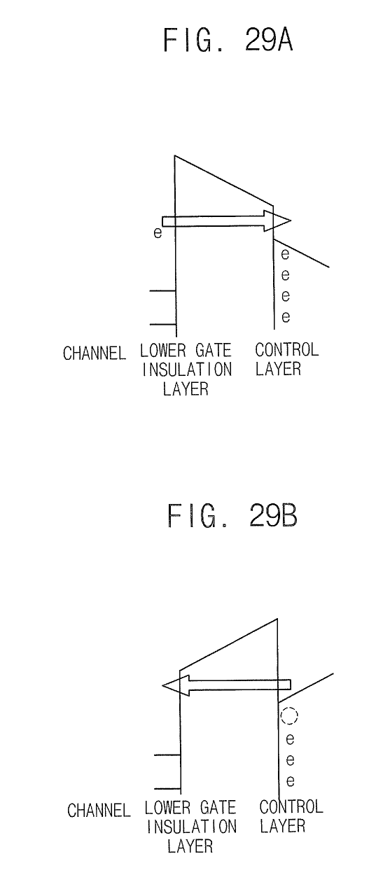

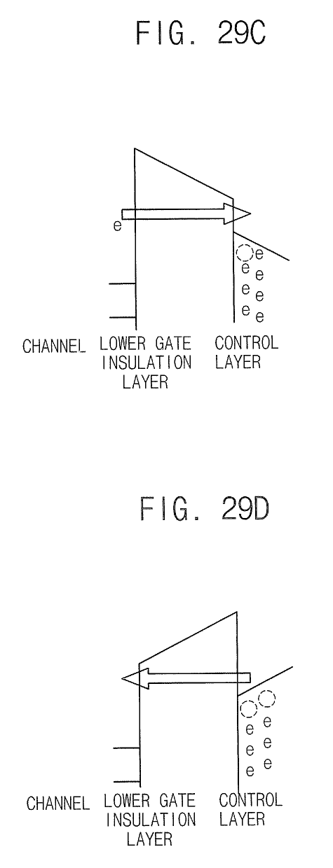

FIGS. 29A to 29D are energy band diagrams illustrating states of a control layer in a transistor when electrons are stored in or detrapped from the control layer. Particularly, FIGS. 29A, 29B, 29C and 29D are energy band diagrams of a channel layer, a lower gate insulation layer and the control layer at a first storing step, a first detrapping step, a second storing step and a second detrapping step, respectively.

Referring to FIG. 29A, electrons tunneling from the channel layer may be stored in the control layer at the first storing step because of the band gaps of the control layer and the lower gate insulation layer.

Referring to FIG. 29B, when the first detrapping step is performed, the energy band may be changed so that electrons stored at a shallow trap site of the control layer may be transferred to the channel layer.

Referring to FIG. 29C, when the second storing step is performed, the amount of electrons stored in the control layer may be increased.

Referring to FIG. 29D, when the second detrapping step is performed, the energy band may be changed again so that electrons stored at the shallow trap site of the control layer may be transferred to the channel layer.

As the above steps are performed repeatedly, electrons may be stored at a deeper trap site, so that the transistor may have good reliability.

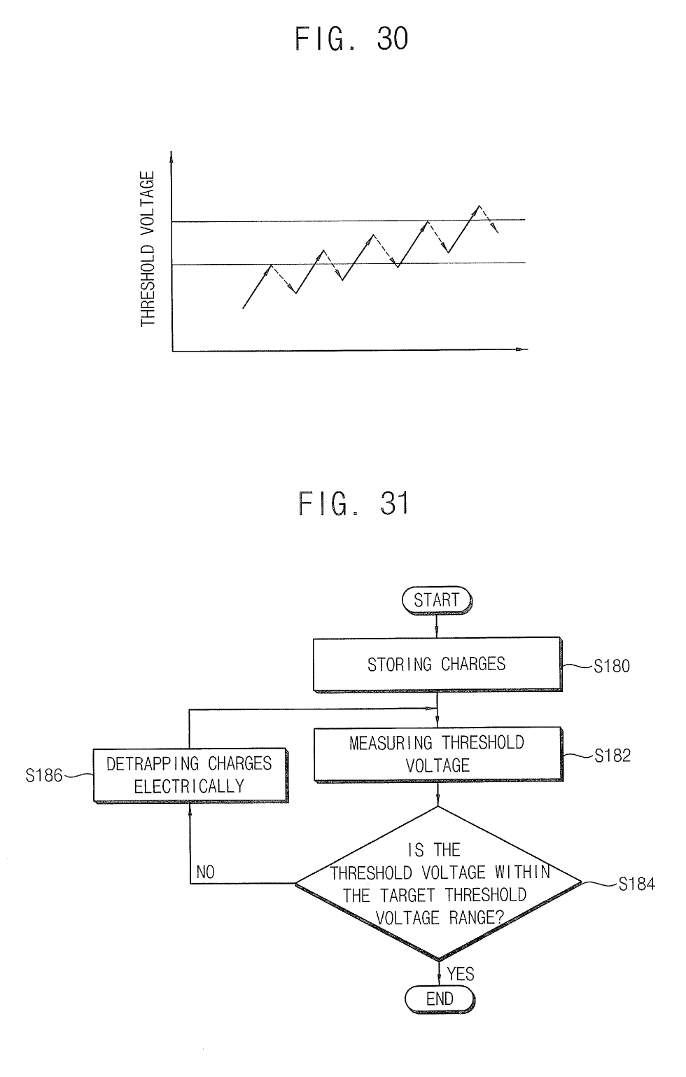

FIG. 30 is a graph showing a threshold voltage of a transistor when storing and detrapping steps are performed repeatedly.

Referring to FIG. 30, when a first storing step is performed, the threshold voltage may be increased, and when a first detrapping step is performed, the threshold voltage may be decreased. However, after performing a second storing step and a second detrapping step, the amount of electrons stored in the control layer is larger than that stored in the control layer when the first detrapping step is performed.

The transistor may have a target threshold voltage by performing the above steps repeatedly.

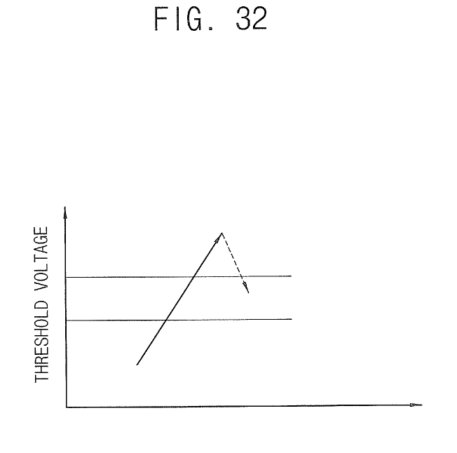

FIG. 31 is a flowchart showing a method of controlling a threshold voltage of a transistor including a control layer in accordance with still other example embodiments.

Referring to FIG. 31, in step S180, negative charges, e.g., electrons may be stored in the control layer of the transistor. The electrons may be stored to a degree at which the transistor may have a threshold voltage higher than the target threshold voltage.

In step S182, an initial threshold voltage of the transistor may be measured with the electrons stored in the control layer.

In step S184, whether the measured threshold voltage is within a range of a target threshold voltage may be decided.

If the measured threshold voltage is higher than the target threshold voltage range, in step S186, electrons stored at a shallow trap site in the control layer may be detrapped. The detrapping step may be performed electrically. Particularly, the detrapping process may be substantially the same as that illustrated with reference to FIG. 28. When the detrapping process is performed, electrons stored at the shallow trap site may be removed, thereby decreasing the threshold voltage.

In step S182, the threshold voltage of the transistor may be measured again, and in step S184, whether the measured threshold voltage is within the target threshold voltage range may be decided again.

If the measured threshold voltage is higher than the target threshold voltage range, the steps S186, S182 and S184 may be performed again.

If the measured threshold voltage is within the target threshold voltage range, the control of the threshold voltage may be finished.

The above method is to decrease the threshold voltage down to the target threshold voltage range by detrapping electrons from the control layer after increasing the threshold voltage initially.

FIG. 32 is a graph showing a threshold voltage of a transistor when storing and detrapping steps are performed.

Referring to FIG. 32, when a storing step is performed, the threshold voltage may be increased. At this time, the transistor may have a threshold voltage higher than the target threshold voltage.

When a detrapping step is performed, the threshold voltage may be decreased because electrons stored at a shallow trap site of the control layer may be transferred to the channel layer. After performing the detrapping step repeatedly, the amount of electrons stored at the shallow trap site of the control layer may be decreased, and thus the threshold voltage may be decreased. Accordingly, the transistor may have a threshold voltage substantially the same as the target threshold voltage.

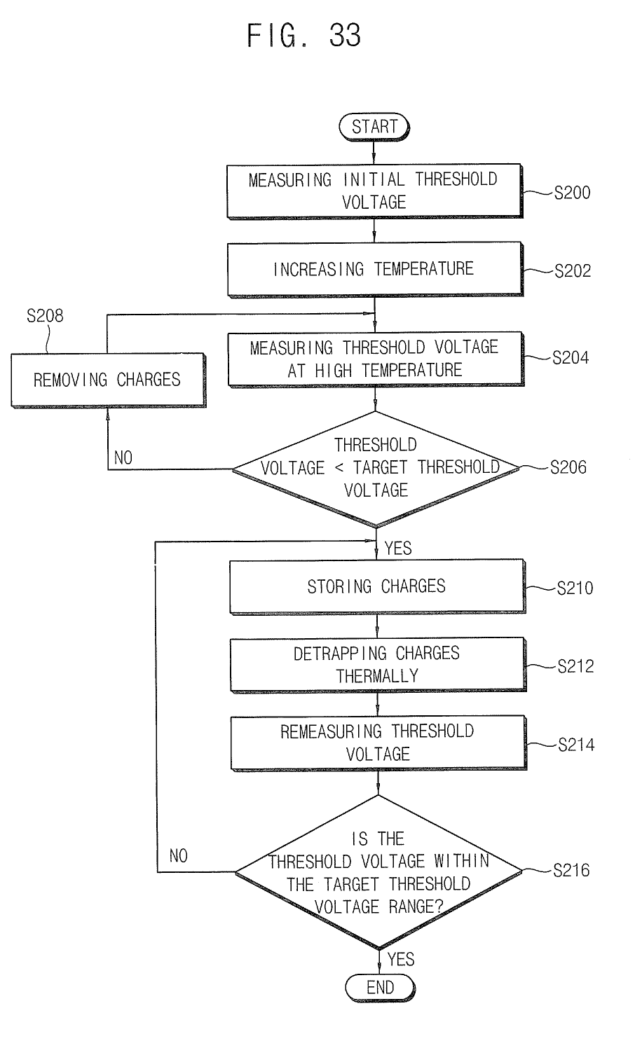

FIG. 33 is a flowchart showing a method of controlling a threshold voltage of a transistor including a control layer in accordance with still other example embodiments.

Referring to FIG. 33, in step S200, an initial threshold voltage of the transistor may be measured.

In step S202, the transistor or a substrate on which the transistor is formed may be heated. The substrate may be heated to a temperature of about 80 to about 300° C., preferably, a temperature of about 150 to about 200° C.

In step S204, the threshold voltage of the transistor at the high temperature may be measured.

In step S206, the measured threshold voltage and a range of a target threshold voltage may be compared to each other. The target threshold voltage range may be a range of a target threshold voltage under the condition of the high temperature.

If the measured threshold voltage is higher than the target threshold voltage range, in step S208, negative charges, e.g., electrons stored in the control layer may be removed.

In step S204, the threshold voltage may be measured again.

If the measured threshold voltage is lower than the target threshold voltage range, electrons may be stored in the control layer. The electrode may be stored by a HCI method or an F-N tunneling method.

In step S212, electrons stored at a shallow trap site of the control layer may be detrapped. The detrapping step may be performed by a heat treatment. Particularly, when the transistor is heated, the electrons stored at the shallow trap site may be removed from the control layer. The heat treatment may include increasing a temperature of the substrate or baking the substrate in a baking oven.

In step S214, the threshold voltage of the transistor may be measured again, and in step S216, whether the measured threshold voltage is within the target threshold voltage range may be decided again.

If the measured threshold voltage is not within the target threshold voltage range, the steps S210, 5212, S214 and S216 may be performed again.

If the measured threshold voltage is within the target threshold voltage range, the control of the threshold voltage may be finished.

Alternatively, the detrapping step may be performed by an electrical method and/or a heat treatment.

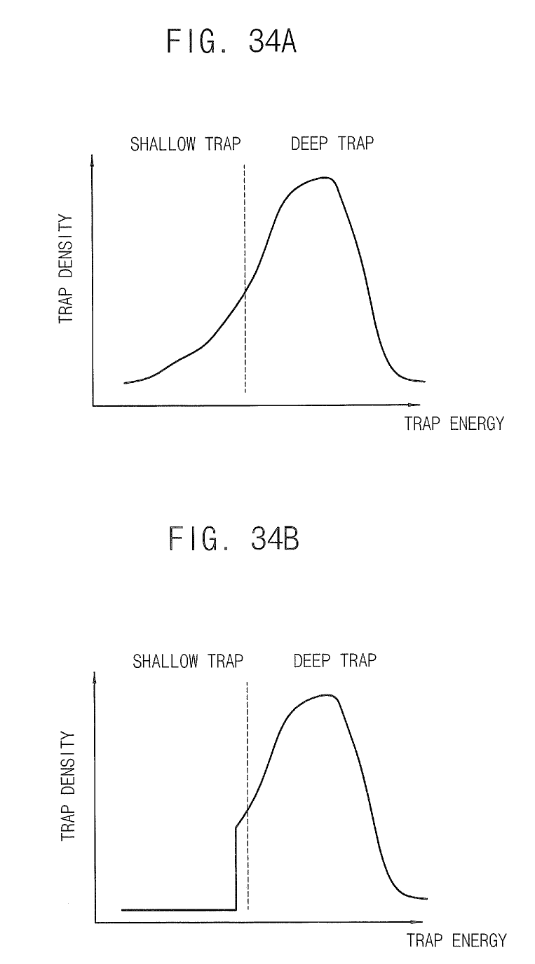

FIG. 34A is a graph showing a charge trap density with respect to a trap energy when electrons are stored in a control layer, and FIG. 34B is a graph showing a charge trap density with respect to a trap energy when electrons are detrapped in a control layer.

Referring to FIG. 34A, when electrons are stored in the control layer by an F-N tunneling method, the electrons may be stored even at a shallow trap site.

Referring to FIG. 34B, when a detrapping process is performed after storing electrons in the control layer, electrons stored at a shallow trap site may be removed.

Experiment on the Characteristics of Electron Retention

Interface trap density was measured according to cycles of program and erase operations of a transistor, so as to check out the leakage of electrons from a control layer.

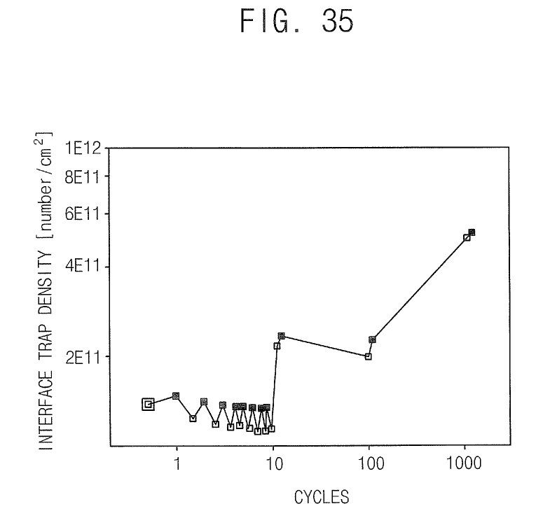

FIG. 35 is a graph showing the interface trap density with respect to the cycles. In FIG. 35, “▪” indicates the erase (removing) operation, and “□” indicates the program (storing) operation.

Referring to FIG. 35, the interface trap density increased as the cycle of the program and erase operations increased. Particularly, when the cycle was equal to or more than 10, the interface trap density remarkably increased. Additionally, the interface trap density increased at the erase operation when a negative voltage is applied to a gate electrode.

However, controlling the threshold voltage of the transistor manufactured in accordance with example embodiments may be completed only by one or two operations. Additionally, a majority carrier device is usually in a low threshold voltage state, and thus the threshold voltage may be controlled only by the program operation. Accordingly, the interface trap density may be increased very slightly. As a result, the threshold voltage of the transistor may not be changed very much because of the interface trap generated while or after controlling the threshold voltage.

According to example embodiments, a transistor having a narrow threshold voltage distribution may be manufactured at a low cost, and this transistor may be adapted to various chips used in RFIDs, EAS tags, EAS sensors, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1.-3. (canceled)

4. A method of manufacturing a transistor, comprising:
forming a gate electrode;
forming a gate insulation layer structure to contact a surface of the gate electrode, the gate insulation layer structure including a lower gate insulation layer, a control layer and an upper gate insulation layer, the control layer controlling a threshold voltage of the transistor;
forming a channel layer to contact a surface of the gate insulation layer structure; and
forming source/drain layers adjacent to but not contacting the gate electrode.

5. The method of claim 4, further comprising trapping electrical charges so that the transistor has a target threshold voltage.

6. The method of claim 5, wherein trapping electrical charges includes applying electrical signals to the source/drain layers.

7. The method of claim 4, wherein at least one of the gate electrode, the control layer and the source/drain layers is formed by a printing process.

8. A method of controlling a threshold voltage of a transistor having a gate insulation layer structure, a channel layer and source/drain layers, the gate insulation layer structure including a lower gate insulation layer, a control layer and an upper gate insulation layer, the method comprising:
measuring an initial threshold voltage of the transistor;
removing negative charges from the control layer when the initial threshold voltage is higher than a target threshold voltage; and
storing negative charges in the control layer so that the transistor has a threshold voltage substantially the same as the target threshold voltage.

9. The method of claim 8, wherein storing the negative charges in the control layer including:
trapping negative charges in the control layer; and
detrapping negative charges stored at a shallow trap site of the control layer.

10. The method of claim 9, wherein detrapping the negative charges is performed electrically or thermally.
